(19) United States
(12) Patent Application Publication
(10) Pub. No.: US 2023/0136686 A1
(43) Pub. Date: May 4, 2023

(54) SEMICONDUCTOR DEVICE AND MANUFACTURING METHOD OF SAME

(71) Applicant: SONY SEMICONDUCTOR SOLUTIONS CORPORATION, Kanagawa (JP)

(72) Inventor: Mitsunari HOSHI, Kanagawa (JP)

(73) Assignee: SONY SEMICONDUCTOR SOLUTIONS CORPORATION, Kanagawa (JP)

(21) Appl. No.: 17/910,509

(22) PCT Filed: Feb. 15, 2021
(86) PCT No.: PCT/JP2021/005406

§ 371 Date: Sep. 9, 2022

(30) Foreign Application Priority Data
Mar. 23, 2020 (JP) 2020-051604

(51) Int. Cl. H01L 21/56; H01L 21/60; H01L 23/00; H01L 21/768; H01L 25/075

(52) U.S. Cl. CPC H01L 21/563; H01L 21/60; H01L 24/16; H01L 21/76898; H01L 25/0753; H01L 24/32; H01L 2224/32225; H01L 2224/16225; H01L 2224/92125

(57) ABSTRACT

To provide a semiconductor device regarding which filling material can be suitably filled in between substrates in a case of disposing a plurality of component parts of the semiconductor device between the substrates, and a manufacturing method of the same. A semiconductor device according to the present disclosure includes a first substrate, a plurality of protruding portions that protrude with respect to a first face of the first substrate, a plurality of types of insulating films that are provided at least between the protruding portions on the first face of the first substrate, a second substrate that is provided facing the first face of the first substrate, and a filling material that is provided between the first substrate and the second substrate, so as to come into contact with the plurality of types of insulating films.

### TECHNICAL FIELD

The present disclosure relates to a semiconductor device and a manufacturing method of the same.

### BACKGROUND ART

When manufacturing a semiconductor device such as a light-emitting device or the like, it is conceivable to dispose a plurality of component parts of the semiconductor device (e.g., a plurality of light-emitting elements or a plurality of connecting portions) between two substrates, and filling in between these substrates with a filling material called an underfill material. This enables these component parts to be protected from foreign matter, and to structurally strengthen these component parts. However, there is a possibility that in cases where filling in between the substrates with the filling material is difficult due to a reason such as the filling speed of the filling material between the substrates being slow or the like, filling defects such as voids may be formed between the substrates.

### CITATION LIST

### Patent Literature

[PTL 1]
JP 2011-171426 A
[PTL 2]
JP 2008-4674 A
[PTL 3]
JP 2016-48752 A

### SUMMARY

### Technical Problem

Forming recessed portions or through holes in one of the substrates prior to filling in between the substrates with the filling material is conceivable, to suppress filling defects such as voids. However, in this case, there is a problem in that the difficulty of filling with the filling material is resolved only in the vicinity of the recessed portions or the through holes.

In a case of filling in between two substrates with a filling material, it is also conceivable to set the wettability of these substrates with respect to the filling material to be high. However, in a case of disposing the plurality of component parts of the semiconductor device between the substrates, how to set the relation between these component parts and the filling material becomes a problem in this case.

Accordingly, the present disclosure provides a semiconductor device regarding which filling material can be suitably filled in between substrates in a case of disposing a plurality of component parts of a semiconductor device between substrates, and a manufacturing method of the same.

### Solution to Problem

A semiconductor device according to a first aspect of the present disclosure includes: a first substrate; a plurality of protruding portions that protrude with respect to a first face of the first substrate; a plurality of types of insulating films that are provided at least between the protruding portions on the first face of the first substrate; a second substrate that is provided facing the first face of the first substrate; and a filling material that is provided between the first substrate and the second substrate, so as to come into contact with the plurality of types of insulating films. Accordingly, for example, facilitating filling in with the filling material by these insulating films enables the filling material to be suitably filled in between the first substrate and the second substrate.

Also, in this first aspect, wettability of the plurality of types of insulating films with respect to the filling material may differ from each other. Accordingly, for example, utilizing the difference in wettability of these insulating films enables the filling material to be suitably filled in between the first substrate and the second substrate.

Also, in this first aspect, the plurality of types of insulating films may include a first insulating film, and a second insulating film of a different type from the first insulating film. Accordingly, for example, facilitating filling in with the filling material by the first insulating film and the second insulating film enables the filling material to be suitably filled in between the first substrate and the second substrate.

Also, in this first aspect, the second insulating film may be provided on the first face of the first substrate, via the first insulating film. Accordingly, for example, utilizing the difference in wettability of the first insulating film and the second insulating film enables the filling material to be suitably filled in between the first substrate and the second substrate.

Also, in this first aspect, the wettability of the second insulating film with respect to the filling material may be higher than the wettability of the first insulating film with respect to the filling material. Accordingly, for example, providing the second insulating film at a location that is not readily filled with the filling material enables the filling material to be suitably filled in between the first substrate and the second substrate.

Also, in this first aspect, the first face of the first substrate may include a first region, and a second region in which a density of the protruding portions is lower than in the first region, and a proportion of an area covered by the second insulating film as to an area of the first face in the second region may be higher than a proportion of the area covered by the second insulating film as to the area of the first face in the first region. Accordingly, for example, providing the second insulating film highly densely at the second region that is not readily filled with the filling material enables the filling material to be suitably filled in between the first substrate and the second substrate.

Also, in this first aspect, the first insulating film may include Si (silicon) and N (nitrogen), and the second insulating film may include Si (silicon) and O (oxygen). Accordingly, for example, the wettability of the second insulating film can be made to be higher than the wettability of the first insulating film.

Also, in this first aspect, the protruding portions may include a light-emitting element that emits light from the first face of the first substrate to a second face. Accordingly, for example, the filling material can be suitably filled in between the first substrate and the second substrate in a case in which the semiconductor device is a light-emitting device.

Also, in this first aspect, the protruding portions may include a connecting portion that electrically connects the first substrate side and the second substrate side. Accordingly, for example, the filling material can be suitably filled in between the first substrate and the second substrate in a case in which the first substrate side and the second substrate side are to be electrically connected by the connecting portions.

Also, in this first aspect, the connecting portion may include a bump or solder. Accordingly, for example, the filling material can be suitably filled in between the first substrate and the second substrate in a case in which the first substrate side and the second substrate side are to be bump-connected or solder-connected.

Also, in this first aspect, the plurality of protruding portions may be disposed non-uniformly on the first face of the first substrate. Accordingly, for example, facilitating filling in with the filling material by the insulating film enables the filling material to be suitably filled in between the first substrate and the second substrate even in a case in which these protruding portions are disposed non-uniformly.

Also, in this first aspect, the filling material may be resin. Accordingly, for example, the filling material can be easily filled in between the first substrate and the second substrate.

Also, in this first aspect, the filling material may be provided between the first substrate and the second substrate, so as to come into contact with the plurality of types of insulating films and the second substrate. Accordingly, for example, space between the first substrate and the second substrate can be wholly filled with the filling material.

Also, in this first aspect, the first substrate may be a semiconductor substrate that includes gallium (Ga) and arsenic (As). Accordingly, for example, the filling material can be suitably filled in between the first substrate and the second substrate in a case of using a GaAs substrate to manufacture a light-emitting device.

Also, in this first aspect, the second insulating film may be provided on the first face of the first substrate and surfaces of the protruding portions, via the first insulating film. Accordingly, for example, the degree of freedom of layout of the second insulating film can be improved.

Also, in this first aspect, the second insulating film may be divided into a plurality of portions that come into contact with the filling material. Accordingly, for example, the degree of freedom of layout of the second insulating film can be improved.

Also, in this first aspect, the plurality of protruding portions may be disposed on the first face of the first substrate so as not to form a regular grid. Accordingly, for example, the filling material can be suitably filled in between the first substrate and the second substrate even in a case in which there is a location that is not readily filled in with the filling material due to such non-uniformity.

Also, the semiconductor device according to this first aspect may further include a plurality of lenses provided on a second face of the first substrate, as part of the first substrate. Accordingly, for example, the filling material can be suitably filled in between the first substrate and the second substrate even in a case in which the first substrate is a substrate for lenses.

Also, in this first aspect, the first substrate may include a plurality of chip regions and a dicing region, and the second insulating film may be provided in at least the dicing region. Accordingly, for example, the filling material can be suitably filled in between the first substrate and the second substrate even in a case in which the dicing region and the vicinity thereof is not readily filled in with the filling material.

A manufacturing method of a semiconductor device according to a second aspect of the present disclosure includes: forming a plurality of protruding portions that protrude with respect to a first face of the first substrate; forming a plurality of types of insulating films at least between the protruding portions on the first face of the first substrate; disposing a second substrate so as to face the first face of the first substrate; and forming a filling material between the first substrate and the second substrate, so as to come into contact with the plurality of types of insulating films. Accordingly, for example, facilitating filling in with the filling material by these insulating films enables the filling material to be suitably filled in between the first substrate and the second substrate.

### BRIEF DESCRIPTION OF DRAWINGS

FIG. 1 is a block diagram illustrating a configuration of a ranging device according to a first embodiment.

FIG. 2 is cross-sectional views illustrating an example of a structure of a light-emitting device according to the first embodiment.

FIG. 3 is a cross sectional view, a plan view, and a perspective view illustrating the structure of the light-emitting device illustrated in B in FIG. 2.

FIG. 4 is cross-sectional views and plan views illustrating structures of light-emitting devices according to the first embodiment and first and second comparative examples thereof.

FIG. 5 is plan views illustrating manufacturing processes of the light-emitting devices according to the first embodiment and the first and second comparative examples thereof

FIG. 6 is cross-sectional views (1/2) illustrating a manufacturing method of the light-emitting device according to the first embodiment.

FIG. 7 is cross-sectional views (2/2) illustrating the manufacturing method of the light-emitting device according to the first embodiment.

FIG. 8 is a cross-sectional view and a plan view illustrating a structure of a light-emitting device according to a second embodiment.

FIG. 9 is a cross-sectional view and a plan view illustrating a structure of a light-emitting device according to a third embodiment.

FIG. 10 is a cross-sectional view and a plan view illustrating a structure of a light-emitting device according to a fourth embodiment.

FIG. 11 is plan views illustrating structures of light-emitting devices according to modifications of the first to fourth embodiments.

FIG. 12 is a cross-sectional view illustrating a structure of a light-emitting device according to another modification of the first to fourth embodiments.

FIG. 13 is a cross-sectional view and a plan view illustrating a structure of a light-emitting device according to a fifth embodiment.

FIG. 14 is a cross-sectional view illustrating details of the structure of the light-emitting device according to the fifth embodiment.

FIG. 15 is a cross-sectional view and a plan view illustrating a structure of a light-emitting device according to a sixth embodiment.

FIG. 16 is a cross-sectional view and a plan view illustrating a structure of a light-emitting device according to a seventh embodiment.

### DESCRIPTION OF EMBODIMENTS

Embodiments of the present disclosure will be described below with reference to the Figures.

### First Embodiment

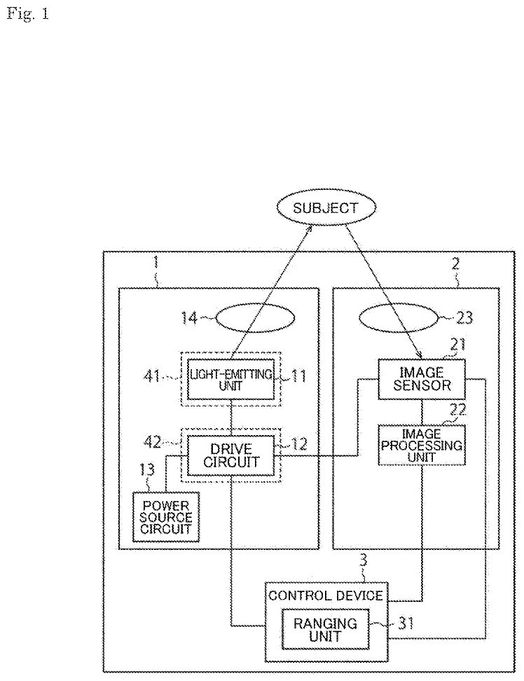

FIG. 1 is a block diagram illustrating a configuration of a ranging device according to a first embodiment.

The ranging device in FIG. 1 includes a light-emitting device 1, an image-capturing device 2, and a control device 3. The ranging device in FIG. 1 radiates light emitted from the light-emitting device 1 onto a subject. The image-capturing device 2 receives the light reflected at the subject and captures images of the subject. The control device 3 uses image signals output from the image-capturing device 2 to measure (calculate) the distance to the subject. The light-emitting device 1 functions as a light source for the image-capturing device 2 to capture images of the subject.

The light-emitting device 1 includes a light-emitting unit 11, a drive circuit 12, a power source circuit 13, and a light-emitting-side optical system 14. The image-capturing device 2 includes an image sensor 21, an image processing unit 22, and an image-capturing-side optical system 23. The control device 3 includes a ranging unit 31.

The light-emitting unit 11 emits laser light which is radiated onto the subject. The light-emitting unit 11 according to the present embodiment has a plurality of light-emitting elements that are arrayed in a two-dimensional array, with each light-emitting element having a VCSEL (Vertical Cavity Surface Emitting Laser) structure, which will be described later. Light emitted from these light-emitting elements is radiated onto the subject. The light-emitting unit 11 according to the present embodiment is provided within a chip called an LD (Laser Diode) chip 41, as illustrated in FIG. 1.

The drive circuit 12 is an electric circuit that drives the light-emitting unit 11. The power source circuit 13 is an electrical circuit that generates power source voltage for the drive circuit 12. In the ranging device in FIG. 1, for example, the power source circuit 13 generates the power source voltage from input voltage supplied from a battery within the ranging device, and the drive circuit 12 drives the light-emitting unit 11 using this power source voltage. The drive circuit 12 according to the present embodiment is provided within a board called an LDD (Laser Diode Driver) board 42, as illustrated in FIG. 1.

The light-emitting-side optical system 14 includes various types of optical elements, and radiates light from the light-emitting unit 11 onto the subject via these optical elements. In the same way, the image-capturing-side optical system 23 includes various types of optical elements, and receives light from the subject via these optical elements.

The image sensor 21 receives light from the subject via the image-capturing-side optical system 23, and converts this light into electrical signals by photoelectric conversion. The image sensor 21 is a CCD (Charge Coupled Device) sensor or a CMOS (Complementary Metal Oxide Semiconductor) sensor, for example. The image sensor 21 according to the present embodiment converts the aforementioned electronic signals from analog signals into digital signals by A/D (Analog to Digital) conversion, and outputs image signals as digital signals to the image processing unit 22. Also, the image sensor 21 according to the present embodiment outputs frame synchronizing signals to the drive circuit 12, and the drive circuit 12 causes the light-emitting unit 11 to emit light at a timing corresponding to a frame cycle at the image sensor 21, on the basis of the frame synchronizing signals.

The image processing unit 22 subjects the image signals output from the image sensor 21 to various types of image processing. The image processing unit 22 includes an image processing processor such as a DSP (Digital Signal Processor) or the like, for example.

The control device 3 controls various types of operations of the ranging device in FIG. 1, and for example, controls light-emitting operations of the light-emitting device 1 and image-capturing operations of the image-capturing device 2. The control device 3 includes, for example, a CPU (Central Processing Unit), ROM (Read Only Memory), RAM (Random Access Memory), and so forth.

The ranging unit 31 measures the distance to the subject on the basis of the image signals output from the image sensor 21 and subjected to image processing by the image processing unit 22. The ranging unit 31 employs the STL (Structured Light) system or ToF (Time of Flight) system, for example, as the ranging system. The ranging unit 31 may further measure the distance between the ranging device and the subject for each part of the subject on the basis of the aforementioned image signals, and identify a three-dimensional form of the subject.

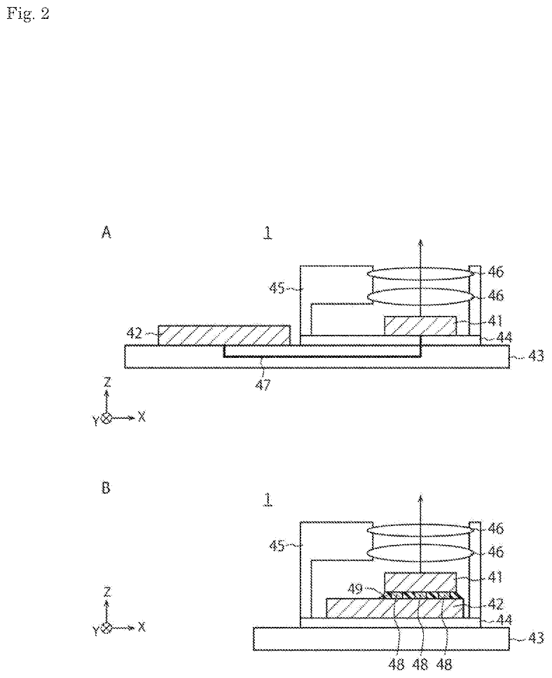

FIG. 2 is cross-sectional views illustrating an example of a structure of the light-emitting device 1 according to the first embodiment. The light-emitting device 1 is an example of a semiconductor device according to the present disclosure.

A in FIG. 2 illustrates a first example of the structure of the light-emitting device 1 according to the present embodiment. The light-emitting device 1 in this example includes the above-described LD chip 41 and the LDD board 42, a mounting board 43, a thermal dissipation substrate 44, a correcting lens holding unit 45, one or more correcting lenses 46, and wiring 47.

A in FIG. 2 illustrates an X axis, a Y axis, and a Z axis, which are perpendicular to each other. An X direction and a Y direction correspond to lateral directions (horizontal directions), and a Z direction corresponds to an upright direction (vertical direction). Also, a +Z direction corresponds to upward, and a −Z direction corresponds to downward. The −Z direction may strictly agree with the gravitational direction, but does not have to strictly agree with the gravitational direction.

The LD chip 41 is disposed on the mounting board 43 via the thermal dissipation substrate 44, and the LDD board 42 is also disposed on the mounting board 43. The mounting board 43 is a printed board, for example. The image sensor 21 and the image processing unit 22 in FIG. 1 are also disposed on the mounting board 43 according to the present embodiment. The thermal dissipation substrate 44 is, for example, a ceramic substrate such as an Al₂O₃ substrate (aluminum oxide) substrate, an AlN (aluminum nitride) substrate, or the like.

The correcting lens holding unit 45 is disposed on the thermal dissipation substrate 44 so as to surround the LD chip 41, and holds the one or more correcting lenses 46 above the LD chip 41. These correcting lenses 46 are included in the above-described light-emitting-side optical system 14 (FIG. 1). Light emitted from the light-emitting unit 11 in the LD chip 41 (FIG. 1) is corrected by these correcting lenses 46, and thereafter is radiated onto the subject (FIG. 1). A in FIG. 2 illustrates two correcting lenses 46 that are held by the correcting lens holding unit 45, as an example.

The wiring 47 is provided on a front face, a rear face, inside, and so forth of the mounting board 41, and electrically connects the LD chip 41 and the LDD board 42. The wiring 47 is, for example, printed wiring provided on the front face and the rear face of the mounting board 41 and via wiring that passes through mounting board 41. The wiring 47 according to the present embodiment further passes through inside of, or nearby, the thermal dissipation substrate 44. B in FIG. 2 illustrates a second example of the structure of the light-emitting device 1 according to the present embodiment. The light-emitting device 1 according to this example includes the same components as the light-emitting device 1 according to the first embodiment, but includes bumps 48 instead of the wiring 47, and further includes an underfill material 49. The bumps 48 are examples of connecting portions according to the present disclosure, and are also examples of protruding portions according to the present disclosure along with later-described light-emitting elements 53, electrodes 54, and connecting pads 62. The underfill material 49 is an example of a filling material according to the present disclosure.

In B of FIG. 2, the LDD board 42 is disposed on the thermal dissipation substrate 44, and the LD chip 41 is disposed on the LDD board 42. Disposing the LD chip 41 on the LDD board 42 in this way enables the size of the mounting board 44 to be reduced as compared to the case of the first example. In B in FIG. 2, the LD chip 41 is disposed on the LDD board 42 via the bumps 48, and is electrically connected to the LDD board 42 by the bumps 48. The bumps 48 are formed of gold (Au), for example. The LD chip 41 may be electrically connected to the LDD board 42 by solder balls instead of the bumps 48.

The underfill material 49 is filled in between the LD chip 41 and the LDD board 42, so as to encompass the bumps 48. The underfill material 49 is, for example, a resin injected between the LD chip 41 and the LDD board 42. Further details of the underfill material 49 will be described later.

The light-emitting device 1 according to the present embodiment will be described below under the assumption of having the structure of the second embodiment illustrated in B in FIG. 2. Note however, that the following description is also applicable to the light-emitting device 1 that has the structure of the first example, with the exception of description of structure unique to the second example.

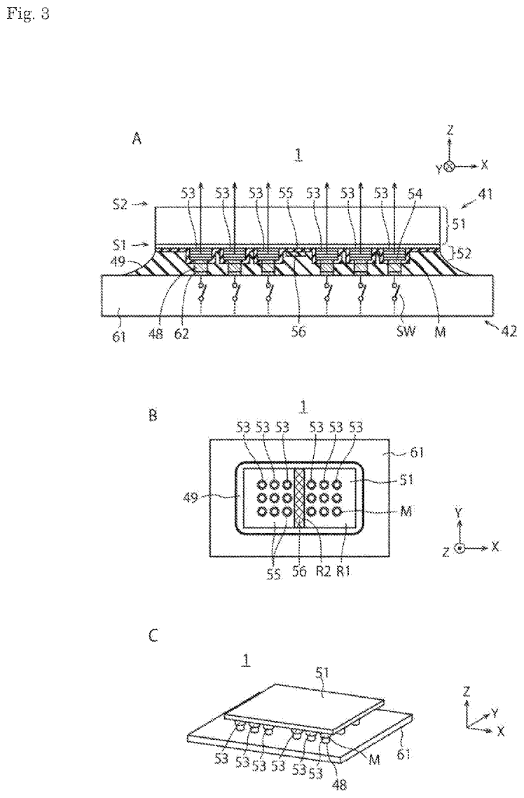

FIG. 3 is a cross sectional view, a plan view, and a perspective view illustrating the structure of the light-emitting device 1 illustrated in B in FIG. 2.

A in FIG. 3 illustrates a cross-section of the LD chip 41 and the LDD board 42 within the light-emitting device 1. As illustrated in A in FIG. 3, the LD chip 41 includes a substrate 51, a laminated film 52, a plurality of the light-emitting elements 53, a plurality of the electrodes 54, a first insulating film 55, and a second insulating film 56. Also, the LDD board 42 includes a substrate 61 and a plurality of the connecting pads 62. B and C in FIG. 3 are a plan view and a perspective view corresponding to A in FIG. 3. Note that the underfill material 49 is omitted from illustration in C in FIG. 3. The structure of the light-emitting device 1 according to the present embodiment will be described below with reference to A through C of FIG. 3.

The substrate 51 is a semiconductor substrate such as a GaAs (gallium arsenide) substrate or the like, for example. A in FIG. 3 illustrates a front face S1 of the substrate 51 facing in the −Z direction, and a rear face S2 of the substrate 51 facing in the +Z direction. The substrate 51 is an example of a first substrate according to the present disclosure. Also, the front face S1 is an example of a first face according to the present disclosure, and the rear face S2 is an example of a second face according to the present disclosure.

The laminated film 52 includes a plurality of layers that are laminated on the front face S1 of the substrate 51. Examples of these layers are an n-type semiconductor layer, an active layer, a p-type semiconductor layer, a light reflection layer, an insulating layer having a light-emission window, and so forth. The laminated film 52 includes a plurality of mesa portions M protruding in the −Z direction. Part of these mesa portions M serve as the plurality of light-emitting elements 53.

The plurality of light-emitting elements 53 are provided on the front face S1 of the substrate 52 as part of the laminated film 52, protruding in the −Z direction with respect to the front face S1 of the substrate 51. The light-emitting elements 53 are an example of protruding portions according to the present disclosure. The light-emitting elements 53 according to the present embodiment have VCSEL structures, and emit light in the +Z direction. Light emitted from the light-emitting elements 53 passes through inside of the substrate 51 from the front face S1 to the rear face S2, and enters the correcting lenses 46 (FIG. 2) from the substrate 51, as illustrated in A in FIG. 3. In this way, the LD chip 41 according to the present embodiment is a back-emitting type VCSEL chip.

B in FIG. 3 illustrates two first regions R1 and one second region R2 of the front face S1 of the substrate 51. The light-emitting elements 53 according to the present embodiment are disposed forming a regular grid within each first region R1, and more specifically, are disposed forming a square grid. Conversely, the light-emitting elements 53 according to the present embodiment are not disposed in the second region R2 provided between the first regions R1. As a result, the front face S1 of the substrate 51 includes the first regions R1 where the density of the light-emitting elements 53 is high and the second region R2 where the density of the light-emitting elements 53 is low, and the light-emitting elements 53 according to the present embodiment are disposed non-uniformly such that the density of the light-emitting elements 53 on the front face S1 of the substrate 51 is not uniform. Note that while the second region R2 does not contain any light-emitting elements 53, light-emitting elements 53 may be contained therein such that the density of the light-emitting elements 53 in the second region R2 is lower than the density of the light-emitting elements 53 in the first regions R1.

The electrodes 54 are formed on lower faces of the light-emitting elements 53. Accordingly, the light-emitting elements 53 and the electrodes 54 are formed in order on the front face S1 of the substrate 51, and protrude in the −Z direction with respect to the front face S1 of the substrate 51. The electrodes 54 are also an example of the protruding portions according to the present disclosure. The electrodes 54 according to the present embodiment are anode electrodes. The LD chip 41 according to the present embodiment further includes cathode electrodes formed on lower faces of the mesa portions M other than the light-emitting elements 53. The light-emitting elements 53 emit light by electric current flowing between corresponding anode electrodes and corresponding cathode electrodes.

The first insulating film 55 and the second insulating film 56 are formed on the front face S1 of the substrate 51, between mutually-adjacent light-emitting elements 53 and so forth. The first insulating film 55 is, for example, a SiN film (silicon nitride film). The second insulating film 56 is an insulating film of a different type from the first insulating film 55, and is a SiO₂ film (silicon oxide film), for example. The first insulating film 55 and the second insulating film 56 are examples of a plurality of types of insulating films according to the present disclosure.

The first insulating film 55 is formed on a lower face of the laminated film 52 and on surfaces (side faces and lower faces) of the light-emitting elements 53, for example. Note however, that lower faces of the electrodes 54 are exposed from the first insulating film 55. The second insulating film 56 is formed on the lower face of the laminated film 52 via the first insulating film 55, for example. In the present embodiment, the first insulating film 55 is formed on almost the entirety of the front face S1 of the substrate 51, whereas the second insulating film 56 is formed only on part of the front face S1 of the substrate 51 (A and B in FIG. 3).

The first insulating film 55 and the second insulating film 56 according to the present embodiment have different wettability from each other with respect to the underfill material 49. For example, in a case in which the first insulating film 55 is a SiN film and the second insulating film 56 is a SiO₂ film, the wettability of the second insulating film 56 with respect to the underfill material 49 is higher than the wettability of the first insulating film 55 with respect to the underfill material 49. Accordingly, the underfill material 49 according to the present embodiment enters the vicinity of the second insulating film 56 more readily.

The wettability of the first insulating film 55 with respect to the underfill material 49 may be measured by any method, but can be measured using contact angle, for example. In a case in which the contact angle of the first insulating film 55 and the underfill material 49 is small, the wettability of the first insulating film 55 with respect to the underfill material 49 is small. An example of the measurement method of the contact angle is the half-angle method. This holds true for the wettability of the second insulating film 56 with respect to the underfill material 49, and also holds true regarding wettability among other materials as well.

As illustrated in B of FIG. 3, the second insulating film 56 according to the present embodiment is formed in the second region R2. Accordingly, the proportion of area of the front face S1 covered by the second insulating film 56 in the second region R2 is greater than the proportion of area of the front face S1 covered by the second insulating film 56 in the first regions R1, as illustrated in plan view in B of FIG. 3. Accordingly, the underfill material 49 according to the present embodiment enters the second region R2 more readily. Note that in the present embodiment, the proportion of area of the front face S1 covered by the second insulating film 56 in the first regions R1 is a value close to 0%, and the proportion of area of the front face S1 covered by the second insulating film 56 in the second region R2 is a value close to 100%. Note however, that as long as the above proportion within the second region R2 is greater than the above proportion within the first regions R1, the above proportion within the first regions R1 may be a value distant from 0%, and the above proportion within the second region R2 may be a value distant from 100%. For example, the second insulating film 56 may be also formed in the first regions R1 and not only in the second region R2.

Note that while the LD chip 41 according to the present embodiment is provided with two types of insulating films (the first insulating film 55 and the second insulating film 56) on the front face S1 of the substrate 51, three or more types of insulating films may be provided on the front face S1 of the substrate 51. Accordingly, the underfill material 49 can be made to readily enter into desired regions, using difference in wettability of these three or more types of insulating films with respect to the underfill material 49.

As described above, the LD chip 41 is disposed on the LDD board 42 via the bumps 48, and the bumps 48 are electrically connected to the LDD board 42. Specifically, the connecting pads 62 are formed on the substrate 61 included in the LDD board 42, and the mesa portions M are formed on the connecting pads 62 via the bumps 48. Each mesa portion M is disposed on a bump 48 via an anode electrode (electrode 54) or a cathode electrode.

The substrate 61 is a semiconductor substrate such as a Si (silicone) substrate or the like, for example, and is disposed in the −Z direction of the substrate 51, so as to face the front face S1 of the substrate 51. The substrate 61 is an example of a second substrate according to the present disclosure.

The connecting pads 62 are formed of a metal such as copper (Cu), for example. The light-emitting elements 53, the electrodes 54, the bumps 48, and the connecting pads 62 protrude in the −Z direction with respect to the front face S1 of the substrate 51. The bumps 48 and the connecting pads 62 are also examples of protruding portions according to the present disclosure.

The LDD board 42 includes the drive circuit 12 for driving the light-emitting unit 11 (FIG. 1). A in FIG. 3 schematically illustrates a plurality of switches SW included in the drive circuit 12. Each of the switches SW is electrically connected to a corresponding light-emitting element 53 via a bump 48. The drive circuit 12 according to the present embodiment is capable of controlling (on/off) these switches SW in increments of individual switches SW. Accordingly, the drive circuit 12 can drive the plurality of light-emitting elements 53 in increments of individual light-emitting elements 53. Thus, the light emitted from the light-emitting unit 11 can be precisely controlled, such as only emitting light from light-emitting elements 53 necessary for ranging, for example. Such individual control of the light-emitting elements 53 can be realized by facilitating electrical connection between the light-emitting elements 53 and the corresponding switches SW, by disposing the LDD board 42 beneath the LD chip 41.

The bumps 48 according to the present embodiment electrically connect the LD chip 41 and the LDD board 42 as described above, and specifically electrically connect electrical circuits and circuit elements on the substrate 51 side with electrical circuits and circuit elements on the substrate 52 side. For example, the above-described switches SW are each electrically connected to corresponding electrodes 54 via the bumps 48.

As illustrated in A in FIG. 3, the underfill material 49 according to the present embodiment fills in between the substrate 51 and the substrate 61, and encompasses the components of the light-emitting device 1, such as the light-emitting elements 53, the electrodes 54, the bumps 48, the connecting pads 62, and so forth. This enables these component parts to be protected from foreign matter, and these component parts to be structurally reinforced. The underfill material 49 is, for example, resin injected between the LD chip 41 and the LDD board 42. The underfill material 49 according to the present embodiment comes into contact with surfaces (lower face and side faces) of the first insulating film 55 and the second insulating film 56, and an upper face of the substrate 61.

The underfill material 49 according to the present embodiment is filled in between the LD chip 41 and the LDD board 42 after the LD chip 41 is diced from a wafer including a plurality of LD chips 41. Accordingly, the underfill material 49 illustrated in A and B in FIG. 3 includes not only portions filled in this gap, but also portions running out from this gap.

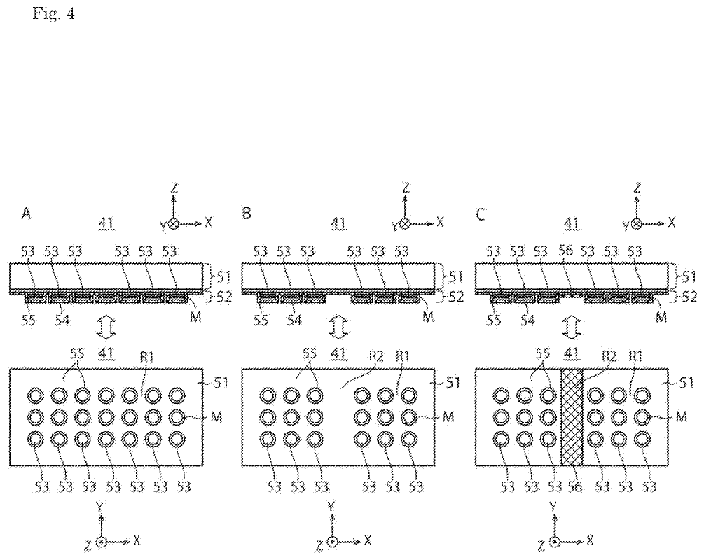

FIG. 4 is cross-sectional views and plan views illustrating structures of light-emitting devices 1 according to the first embodiment and first and second comparative examples thereof.

The cross-sectional view and the plan view in A in FIG. 4 illustrate the structure of the LD chip 41 in the light-emitting device 1 according to the first comparative example. The substrate 51 according to the present comparative example has no second region R2 as illustrated in the plan view in A in FIG. 4, and only has the first region R1. Accordingly, the light-emitting elements 53 according to the present comparative example are disposed generally uniform. Also, the LD chip 41 according to the present comparative example includes the first insulating film 55 but does not include the second insulating film 56.

The cross-sectional view and the plan view in B in FIG. 4 illustrate the structure of the LD chip 41 in the light-emitting device 1 according to the second comparative example. The substrate 51 according to the present comparative example has the first regions R1 and the second region R2, as illustrated in the plan view in B in FIG. 4. Accordingly, the light-emitting elements 53 according to the present comparative example are disposed non-uniformly. Also, the LD chip 41 according to the present comparative example includes the first insulating film 55 but does not include the second insulating film 56.

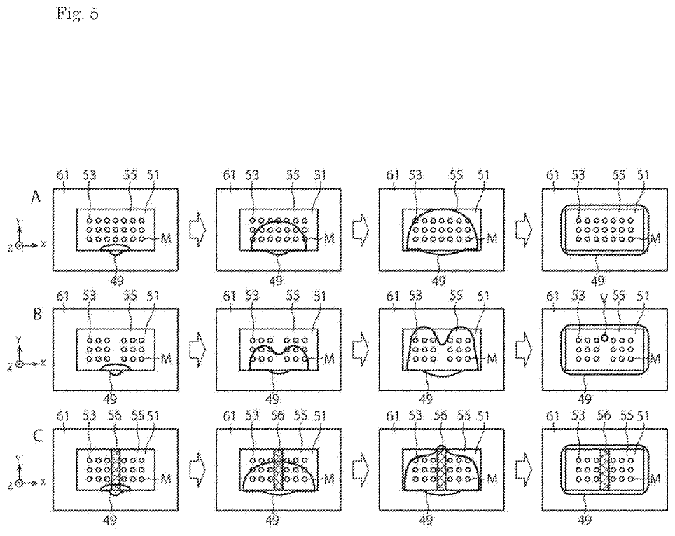

The cross-sectional view and the plan view in C in FIG. 4 illustrate the structure of the LD chip 41 in the light-emitting device 1 according to the first embodiment. The substrate 51 according to the present embodiment has the first regions R1 and the second region R2, as illustrated in the plan view in C in FIG. 4. Accordingly, the light-emitting elements 53 according to the present embodiment are disposed non-uniformly. Also, the LD chip 41 according to the present embodiment includes the first insulating film 55 and the second insulating film 56. FIG. 5 is plan views illustrating manufacturing processes of the light-emitting devices 1 according to the first embodiment and first and second comparative examples thereof.

A in FIG. 5 illustrates a flow of processes of injecting the underfill material 49 between the substrate 51 and the substrate 61 according to the first comparative example, in four stages. The underfill material 49 according to the present comparative example is injected between the substrate 51 and the substrate 61 from a point at the middle of a −Y direction side of the substrate 51, as can be seen from the diagram for a first stage. The underfill material 49 injected from this point gradually spreads through the space between the substrate 51 and the substrate 61, as can be seen from the diagrams for a second stage and a third stage. The underfill material 49 according to the present comparative example fills in the entire space between the substrate 51 and the substrate 61, as can be seen from the diagram for a fourth stage.

B in FIG. 5 illustrates a flow of processes of injecting the underfill material 49 between the substrate 51 and the substrate 61 according to the second comparative example, in four stages. The underfill material 49 according to the present comparative example is also injected between the substrate 51 and the substrate 61 from a point at the middle of a −Y direction side of the substrate 51, as can be seen from the diagram for the first stage. The underfill material 49 injected from this point gradually spreads through the space between the substrate 51 and the substrate 61, as can be seen from the diagrams for the second stage and the third stage. However, the flow of the underfill material 49 according to the present comparative example differs from the flow of the underfill material 49 according to the first comparative example. The underfill material 49 according to the present comparative example fills in almost the entire space between the substrate 51 and the substrate 61, but a void V is formed between the substrate 51 and the substrate 61, as can be seen from the diagram for the fourth stage.

The underfill material 49 according to the first and second comparative examples spreads between the substrate 51 and the substrate 61 by capillary action, due to the narrowness in distance between the substrate 51 and the substrate 61. This capillary action becomes stronger among protruding portions such as the light-emitting elements 53. The reason is that the width between the protruding portions is narrow. The underfill material 49 rapidly spreads in the first regions R1 in the first and second comparative examples, but the underfill material 49 slowly spreads in the second region R2 in the second comparative example. B in FIG. 5 illustrates the way in which the underfill material 49 slowly spreads in the second region R2 in the second stage and the third stage. Accordingly, the void V is formed in the second region R2 in the fourth stage in B in FIG. 5.

C in FIG. 5 illustrates a flow of processes of injecting the underfill material 49 between the substrate 51 and the substrate 61 according to the first embodiment, in four stages. The underfill material 49 according to the present embodiment is also injected between the substrate 51 and the substrate 61 from a point at the middle of a −Y direction side of the substrate 51, as can be seen from the diagram for the first stage. The underfill material 49 injected from this point gradually spreads through the space between the substrate 51 and the substrate 61, as can be seen from the diagrams for the second stage and the third stage. However, the flow of the underfill material 49 according to the present embodiment differs from the flow of the underfill material 49 according to the second comparative example. The underfill material 49 according to the present embodiment then fills in the entire space between the substrate 51 and the substrate 61, as can be seen from the diagram for the fourth stage.

The light-emitting elements 53 according to the present embodiment are disposed in the same way as the light-emitting elements 53 according to the second comparative example, and accordingly it would appear at first that the underfill material 49 according to the present embodiment would slowly spread in the second region R2. However, the second region R2 according to the present embodiment is provided with the second insulating film 56 that has high wettability as compared to the first insulating film 55. Accordingly, the underfill material 49 enters the second region R2 according to the present embodiment more readily. This enables the underfill material 49 to quickly spread within the second region R2, and voids V can be suppressed from being formed in the second region R2.

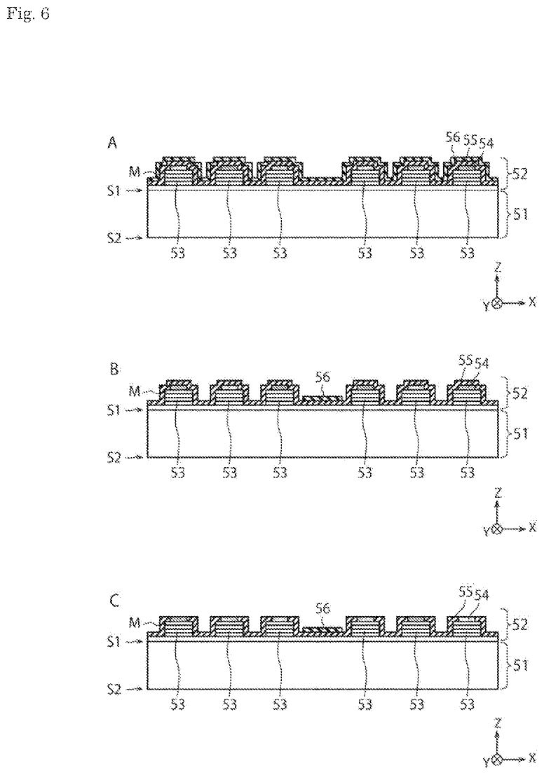

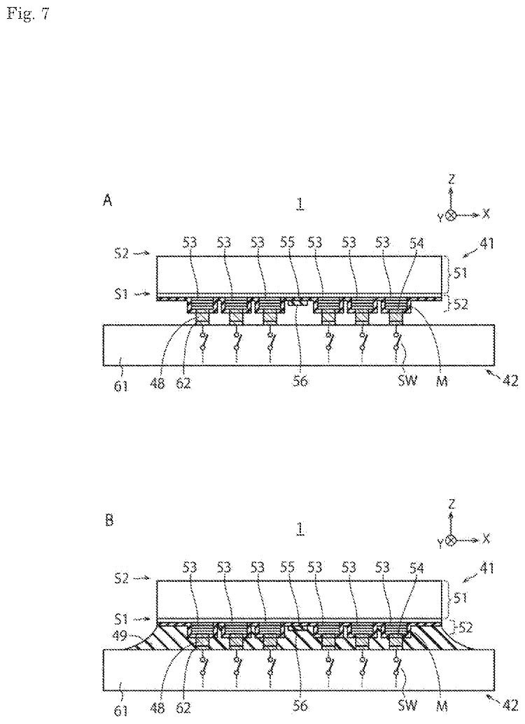

FIG. 6 and FIG. 7 are cross-sectional diagrams illustrating a manufacturing method of the light-emitting device 1 according to the first embodiment.

First, the substrate 51 is prepared (A in FIG. 6). In A in FIG. 6, the front face S1 of the substrate 51 is facing in the +Z direction, and the rear face S2 of the substrate 51 is facing in the −Z direction. Next, the laminated film 52 is formed on the front face S1 of the substrate 51 and the laminated film 52 is etched so as to include the plurality of light-emitting elements 53 (mesa portions M) (A in FIG. 6). Next, the plurality of electrodes 54 are formed on the surfaces (upper faces) of these light-emitting elements 53, and the first insulating film 55 and the second insulating film 56 are formed on the front face S1 of the substrate 51 so as to cover the laminated film 52, the light-emitting elements 53, and the electrodes 54 (A in FIG. 6).

Next, the second insulating film 56 is etched (B in FIG. 6). This removes the second insulating film 56 from other than the above-described second region R2.

Next, the first insulating film 55 is etched (C in FIG. 6). This exposes the electrodes 54 from the first insulating film 55. Thus, the first insulating film 55 and the second insulating film 56 are formed between mutually adjacent light-emitting elements 53.

Next, the substrate 51 is disposed on the substrate 61 (A in FIG. 7). At this time, the substrate 51 is disposed on the upper face of the substrate 61 such that the front face S1 faces in the −Z direction, and the rear face S2 of the substrate 51 faces the +Z direction. A in FIG. 7 illustrates the plurality of connecting pads 62 formed on the upper face of the substrate 61 in advance. The substrate 51 is disposed on the substrate 61 such that the electrodes 48 are disposed on the connecting pads 62 via the bumps 48. Accordingly, the substrate 51 side is electrically connected to the substrate 61 side.

Next, the underfill material 49 is injected between the substrate 51 and the substrate 61 (B in FIG. 7). At this time, the flow of the underfill material 49 is promoted by the second insulating film 56. The underfill material 49 illustrated in B in FIG. 7 encompasses the components of the light-emitting device 1, such as the light-emitting elements 53, the electrodes 54, the bumps 48, the connecting pads 62, and so forth, and is also in contact with the first insulating film 55, the second insulating film 56, the substrate 61, and so forth. Thus, the light-emitting device 1 according to the present embodiment is manufactured.

As described above, the light-emitting device 1 according to the present embodiment includes the first insulating film 55 and the second insulating film 56 formed between mutually adjacent light-emitting elements 53 on the front face S1 of the substrate 51, and so forth. Thus, according to the present embodiment, the underfill material 49 can be suitably filled in between the substrate 51 and the substrate 61 between which these light-emitting elements 53 are interposed.

### Second Embodiment

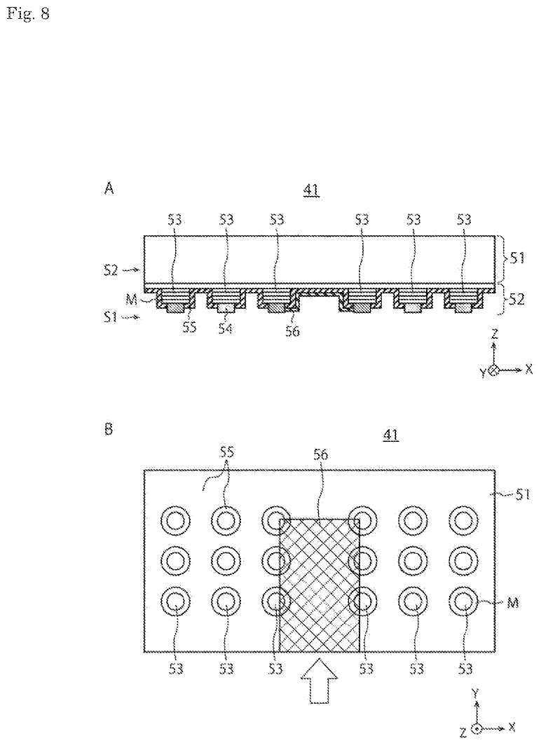

FIG. 8 is a cross-sectional view and a plan view illustrating a structure of a light-emitting device 1 according to a second embodiment.

A in FIG. 8 illustrates a cross-section of the LD chip 41 within the light-emitting device 1. B in FIG. 8 is a plan view corresponding to A in FIG. 8. The light-emitting device 1 according to the present embodiment includes the same components as the light-emitting device 1 according to the first embodiment, but the shape of the second insulating film 56 according to the present embodiment is different from the shape of the second insulating film 56 according to the first embodiment. The arrow shown in B in FIG. 8 indicates the injection position of the underfill material 49.

The second insulating film 56 according to the present embodiment is formed not only on the lower face of the laminated film 52 but also on the surfaces (side faces and lower faces) of the light-emitting elements 53, as illustrated in A and B in FIG. 8. In this way, the second insulating film 56 may be formed on the surfaces of the light-emitting elements 53. Thus, the degree of freedom of layout of the second insulating film 56 can be improved. The second insulating film 56 according to the present embodiment is formed on the surfaces of the light-emitting elements 53 in the vicinity of the second region R2, and accordingly the underfill material 49 can be made to enter the second region R2 more readily.

### Third Embodiment

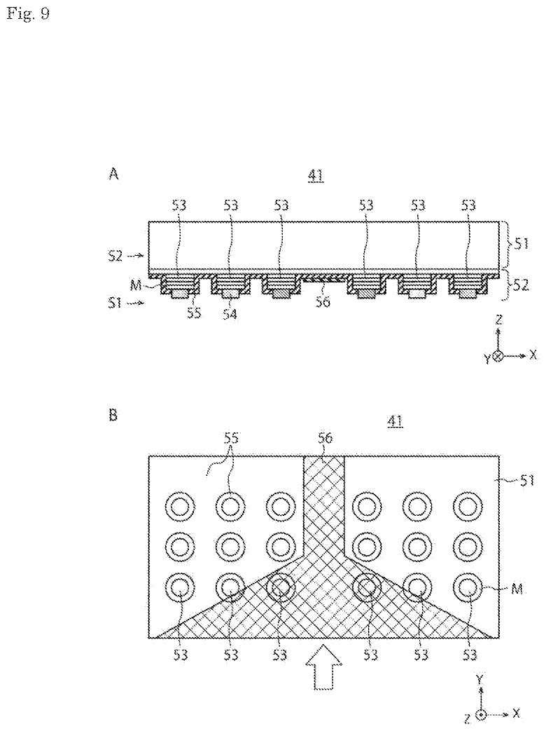

FIG. 9 is a cross-sectional view and a plan view illustrating a structure of a light-emitting device 1 according to a third embodiment.

A in FIG. 9 illustrates a cross-section of the LD chip 41 within the light-emitting device 1. B in FIG. 9 is a plan view corresponding to A in FIG. 9. The light-emitting device 1 according to the present embodiment includes the same components as the light-emitting device 1 according to the first and second embodiments, but the shape of the second insulating film 56 according to the present embodiment is different from the shapes of the second insulating film 56 according to the first and second embodiments. The arrow shown in B in FIG. 9 indicates the injection position of the underfill material 49.

The second insulating film 56 is formed over a broad range in the vicinity of the injection position of the underfill material 49 in the present embodiment. This enables stalling of the flow of the underfill material 49 in the vicinity of the injection position of the underfill material 49 to be suppressed, and the underfill material 49 can be readily spread throughout the entire space between the substrate 51 and the substrate 61. The second insulating film 56 according to the present embodiment is further formed not only on the lower face of the laminated film 52 but also on the surfaces (side faces and lower faces) of the light-emitting elements 53, as illustrated in B in FIG. 9.

### Fourth Embodiment

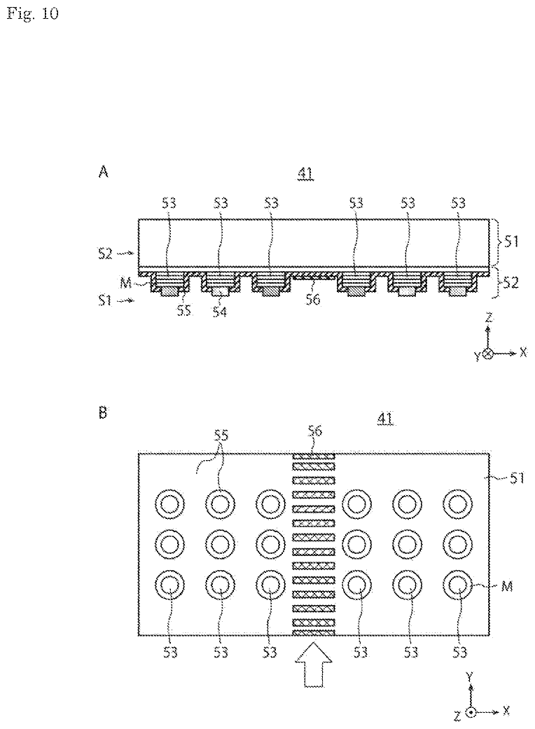

FIG. 10 is a cross-sectional view and a plan view illustrating a structure of a light-emitting device 1 according to a fourth embodiment.

A in FIG. 10 illustrates a cross-section of the LD chip 41 within the light-emitting device 1. B in FIG. 10 is a plan view corresponding to A in FIG. 10. The light-emitting device 1 according to the present embodiment includes the same components as the light-emitting device 1 according to the first to third embodiments, but the shape of the second insulating film 56 according to the present embodiment is different from the shape of the second insulating film 56 according to the first to third embodiments. The arrow shown in B in FIG. 10 indicates the injection position of the underfill material 49.

The second insulating film 56 according to the present embodiment is divided into a plurality of portions, as illustrated in B in FIG. 10. The underfill material 49 according to the present embodiment spreads between the substrate 51 and the substrate 61 while coming into contact with these portions. In this way, the second insulating film 56 according to the present embodiment may have a shape in which one portion continuously spreads, or may have a shape in which a plurality of portions are intermittently arrayed. Also, the plurality of these portions may be disposed far away from each other. Thus, the degree of freedom of layout of the second insulating film 56 can be improved.

### Modifications of First to Fourth Embodiments

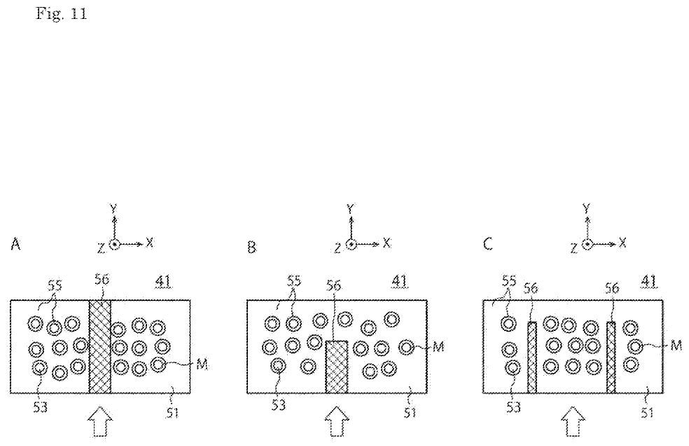

FIG. 11 is plan views illustrating structures of light-emitting devices 1 according to modifications of the first to fourth embodiments.

In the modification illustrated in A in FIG. 11, the plurality of light-emitting elements 53 are disposed so as not to form a regular grid such as a square grid. The second insulating film 56 according to the present modification is disposed in a broad region between a righthand group including nine light-emitting elements 53 and a lefthand group including nine light-emitting elements 53, and has the same shape as the second insulating film 56 according to the first embodiment. Thus, the underfill material 49 can be made to readily enter this broad region. In the present modification, the second insulating film 56 may further be disposed between light-emitting elements 53 where the distance between the light-emitting elements 53 is long.

In the modification illustrated in B in FIG. 11 as well, the plurality of light-emitting elements 53 are disposed so as not to form a regular grid such as a square grid. In the present modification, no light-emitting elements 53 are disposed in the vicinity of the injection position of the underfill material 49, but light-emitting elements 53 are disposed in a region in the +Y direction from the injection position of the underfill material 49, and accordingly no second insulating film 56 is disposed in this region.

In the modification illustrated in C in FIG. 11 as well, the plurality of light-emitting elements 53 are disposed so as not to form a regular grid such as a square grid. In the present modification, there are two broad regions present where no light-emitting elements 53 are disposed, and accordingly the second insulating film 56, divided into two, is disposed in these regions.

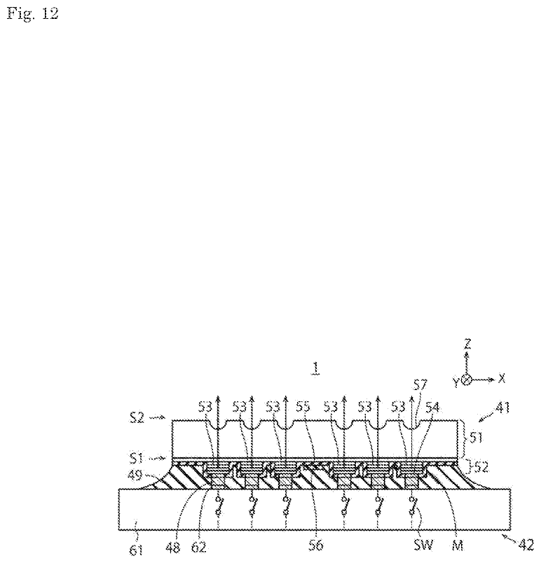

FIG. 12 is a cross-sectional view illustrating a structure of a light-emitting device 1 according to another modification of the first to fourth embodiments.

The light-emitting device 1 according to the present modification includes, in addition to the same components as the light-emitting device 1 according to the first embodiment, a plurality of lenses 57. In the present modification, the LD chip 41 includes the plurality of light-emitting elements 53 on the front face S1 of the substrate 51, and also includes these lenses 57 on the rear face S2 of the substrate 51. The lenses 57 according to the present modification correspond to the light-emitting elements 53 in a one on one manner, with each lens 57 being disposed in the +Z direction of one light-emitting element 53.

The lenses 57 according to the present modification are provided on the rear face S2 of the substrate 51 as part of the substrate 51. Specifically, the lenses 57 according to the present modification are concave lenses, and are formed as part of the substrate 51 by etching the rear face S2 of the substrate 51 in concave shapes. Note that the lenses 57 according to the present modification may be lenses other than concave lenses (convex lenses).

Light emitted from the plurality of light-emitting elements 53 passes through the inside of the substrate 51 from the front face S1 to the rear face S2, and enters the plurality of lenses 57. As illustrated in FIG. 12, the light emitted from each light-emitting element 53 enters one corresponding lens 57. Thus, light emitted from the light-emitting elements 53 can be formed into suitable forms by the corresponding lenses 57.

Note that light that has passed through the lenses 57 according to the present modification pass through the correcting lenses 46 (FIG. 2), and is radiated onto the subject (FIG. 1).

The light-emitting device 1 according to the second and third embodiments, and the light-emitting device 1 according to modifications thereof, can be manufactured by the method illustrated in FIG. 6 and FIG. 7, for example. Note however, that when manufacturing the light-emitting device 1 according to the second or third embodiments, the second insulating film 56 is etched to the form according to the second or third embodiments. Also, when manufacturing the light-emitting device 1 according to any of the modifications in A to C in FIG. 11, the light-emitting elements 53 are disposed according to the layouts of the modifications, and the second insulating film 56 is etched to the forms in modifications. Further, when manufacturing the light-emitting device 1 according to the modification in FIG. 12, the lenses 57 are formed in the substrate 51 after the process illustrated in B in FIG. 7, for example.

### Fifth Embodiment

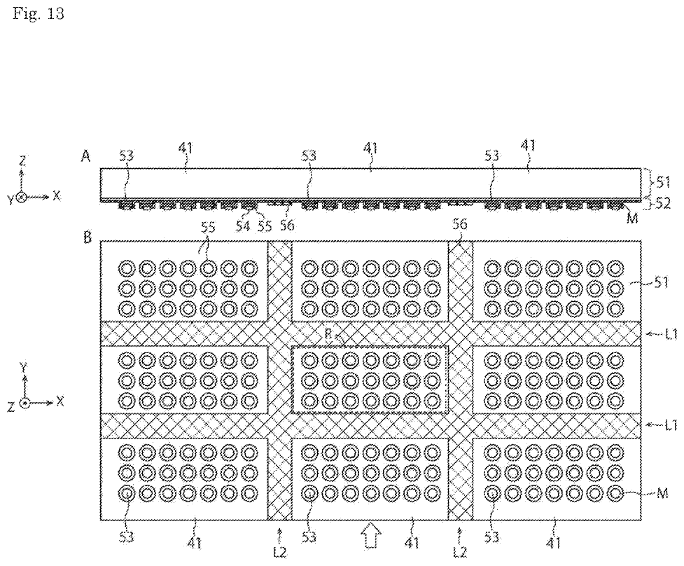

FIG. 13 is a cross-sectional view and a plan view illustrating a structure of a light-emitting device 1 according to a fifth embodiment.

A and B in FIG. 13 illustrate a cross-section of a wafer prior to dicing into a plurality of the LD chips 41. This wafer includes the same components as the light-emitting device 1 according to the first to third embodiments, but the shape of the second insulating film 56 according to the present embodiment is different from the shapes of the second insulating film 56 according to the first to third embodiments. The arrow shown in B in FIG. 13 indicates the injection direction of the underfill material 49.

B in FIG. 13 illustrates a region (chip region) R corresponding to one LD chip 41, and a plurality of X direction lines L1 and a plurality of Y direction lines L2 making up dicing regions. In the present embodiment, cutting the above wafer along these lines L1 and L2 divides the above wafer into the plurality of LD chips 41. B in FIG. 13 illustrates nine chip regions R for manufacturing nine LD chips 41.

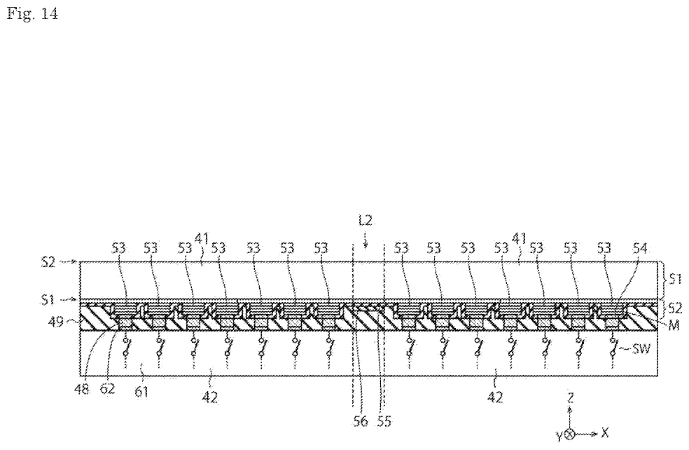

The light-emitting device 1 according to the present embodiment can be manufactured by the method illustrated in FIG. 6 and FIG. 7, for example. Note however, that when manufacturing the light-emitting device 1 according to the present embodiment, the processes illustrated in A in FIG. 6 to B in FIG. 7 are performed prior to cutting the above wafer into the plurality of LD chips 41. In the process illustrated in A in FIG. 7, an upper wafer including the plurality of LD chips 41 is disposed on a lower wafer including a plurality of the LDD boards 42. In the processing in B in FIG. 7, the underfill material 49 is injected between the upper wafer and the lower wafer (see FIG. 14). FIG. 14 is a cross-sectional view illustrating details of the structure of the light-emitting device 1 according to the fifth embodiment, and specifically illustrates the underfill material 49 injected between the upper wafer and the lower wafer. Thereafter, in the present embodiment, the upper wafer and the lower waver are cut together along the lines L1 and L2, thereby manufacturing a plurality of the light-emitting devices 1.

As illustrated in B in FIG. 13, the second insulating film 56 according to the present embodiment is disposed on the lines L1 and L2. The reason is that the underfill material 49 does not readily spread in the vicinity of the lines L1 and L2, since no light-emitting elements 53 are formed on the lines L1 and L2. Disposing the second insulating film 56 on the lines L1 and L2 in the present embodiment enables spreading of the underfill material 49 in the vicinity of the lines L1 and L2 to be promoted.

Note that in each chip region R according to the present embodiment, the light-emitting elements 53 are disposed generally uniformly, but may be disposed non-uniformly. In a case in which the light-emitting elements 53 are disposed non-uniformly in each of the chip regions R, the second insulating film 56 may be disposed in a region where the density of the light-emitting elements 53 is low in each of the chip regions R. Thus, the second insulating film 56 according to the present embodiment may be disposed in both within the chip region R and within the dicing regions.

### Sixth Embodiment

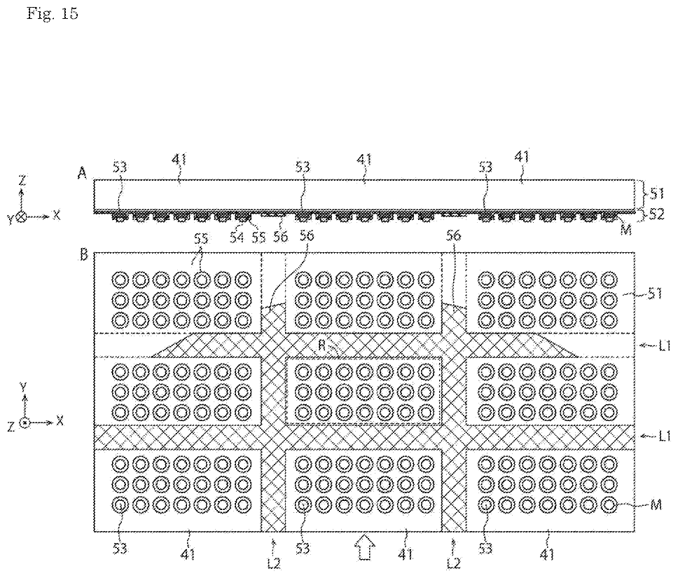

FIG. 15 is a cross-sectional view and a plan view illustrating a structure of a light-emitting device 1 according to a sixth embodiment.

A and B in FIG. 15 illustrate a cross-section of a wafer (upper wafer) prior to dicing into a plurality of LD chips 41. The light-emitting device 1 according to the present embodiment includes the same components as the light-emitting device 1 according to the fifth embodiment, but the shape of the second insulating film 56 according to the present embodiment is different from the shape of the second insulating film 56 according to the fifth embodiment. The arrow shown in B in FIG. 15 indicates the injection direction of the underfill material 49.

The second insulating film 56 according to the present embodiment is disposed only at an upstream region of the flow of the underfill material 49 in the dicing regions, instead of within the entirety of the dicing regions (lines L1, L2). The reason is that it is conceivable that promoting the flow of the underfill material 49 at the upstream region of the flow of the underfill material 49 will promote the flow of the underfill material 49 at a downstream region of the flow of the underfill material 49 as well.

The light-emitting device 1 according to the present embodiment can be manufactured by the method illustrated in FIG. 6 and FIG. 7, for example, in the same way as the light-emitting measures 1 according to the fifth embodiment. Note however, that when manufacturing the light-emitting device 1 according to the present embodiment, the second insulating film 56 is etched to the form according to the present embodiment.

### Seventh Embodiment

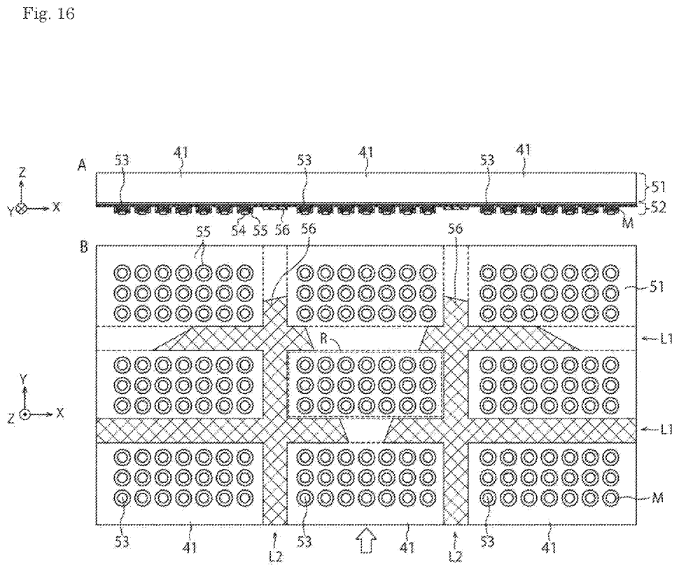

FIG. 16 is a cross-sectional view and a plan view illustrating a structure of a light-emitting device 1 according to a seventh embodiment.

A and B in FIG. 16 illustrate a cross-section of a wafer (upper wafer) prior to dicing into a plurality of LD chips 41. The light-emitting device 1 according to the present embodiment includes the same components as the light-emitting device 1 according to the fifth embodiment, but the shape of the second insulating film 56 according to the present embodiment is different from the shape of the second insulating film 56 according to the fifth embodiment. The arrow shown in B in FIG. 16 indicates the injection direction of the underfill material 49.

The second insulating film 56 according to the present embodiment is disposed only at the upstream region of the flow of the underfill material 49 in the dicing regions, instead of within the entirety of the dicing regions (lines L1, L2). The reason is that it is conceivable that promoting the flow of the underfill material 49 at the upstream region of the flow of the underfill material 49 will promote the flow of the underfill material 49 at the downstream region of the flow of the underfill material 49 as well.

Also, the second insulating film 56 according to the present embodiment is divided into a plurality of portions, as illustrated in B in FIG. 16. The underfill material 49 according to the present embodiment spreads between the substrate 51 and the substrate 61 while coming into contact with these portions. In this way, the insulating film 56 according to the present embodiment may have just one portion, or may have a plurality of portions. Thus, the degree of freedom of layout of the second insulating film 56 can be improved.

The light-emitting device 1 according to the present embodiment can be manufactured by the method illustrated in FIG. 6 and FIG. 7, for example, in the same way as the light-emitting measures 1 according to the fifth embodiment. Note however, that when manufacturing the light-emitting device 1 according to the present embodiment, the second insulating film 56 is etched to the form according to the present embodiment.

Note that while the light-emitting device 1 according to the first to seventh embodiments is used as a light source for a ranging device, usage may be made in other forms. For example, the light-emitting device 1 according to these embodiments may be used as a light source in optical equipment such as a printer or the like, or may be used as an illumination device.

Although embodiments of the present disclosure have been described, these embodiments may be carried out with various changes made thereto, without departing from the essence of the present disclosure. For example, two or more embodiments may be carried out in combination.

Note that the present disclosure may assume the following configurations.

(1) A semiconductor device, including:

a first substrate;

a plurality of protruding portions that protrude with respect to a first face of the first substrate;

a plurality of types of insulating films that are provided at least between the protruding portions on the first face of the first substrate;

a second substrate that is provided facing the first face of the first substrate; and a filling material that is provided between the first substrate and the second substrate, so as to come into contact with the plurality of types of insulating films.

(2) The semiconductor device according to (1), wherein wettability of the plurality of types of insulating films with respect to the filling material differs from each other.

(3) The semiconductor device according to (1), wherein the plurality of types of insulating films include a first insulating film, and a second insulating film of a different type from the first insulating film.

(4) The semiconductor device according to (3), wherein the second insulating film is provided on the first face of the first substrate, via the first insulating film.

(5) The semiconductor device according to (3), wherein the wettability of the second insulating film with respect to the filling material is higher than the wettability of the first insulating film with respect to the filling material.

(6) The semiconductor device according to (3), wherein

the first face of the first substrate includes a first region, and a second region in which a density of the protruding portions is lower than in the first region, and

a proportion of an area covered by the second insulating film as to an area of the first face in the second region is higher than a proportion of the area covered by the second insulating film as to the area of the first face in the first region.

(7) The semiconductor device according to (3), wherein

the first insulating film includes Si (silicon) and N (nitrogen), and

the second insulating film includes Si (silicon) and O (oxygen).

(8) The semiconductor device according to (1), wherein the protruding portions include a light-emitting element that emits light from the first face of the first substrate to a second face.

(9) The semiconductor device according to (1), wherein the protruding portions include a connecting portion that electrically connects the first substrate side and the second substrate side.

(10) The semiconductor device according to (9), wherein the connecting portion includes a bump or solder.

(11) The semiconductor device according to (1), wherein the plurality of protruding portions are disposed non-uniformly on the first face of the first substrate.

(12) The semiconductor device according to (1), wherein the filling material is resin.

(13) The semiconductor device according to (1), wherein the filling material is provided between the first substrate and the second substrate, so as to come into contact with the plurality of types of insulating films and the second substrate.

(14) The semiconductor device according to (1), wherein the first substrate and the second substrate are semiconductor substrates.

(15) The semiconductor device according to (1), wherein the first substrate is a semiconductor substrate that includes gallium (Ga) and arsenic (As).

(16) The semiconductor device according to (3), wherein the second insulating film is provided on the first face of the first substrate and surfaces of the protruding portions, via the first insulating film.

(17) The semiconductor device according to (3), wherein the second insulating film is divided into a plurality of portions that come into contact with the filling material.

(18) The semiconductor device according to (1), wherein the plurality of protruding portions are disposed on the first face of the first substrate so as not to form a regular grid.

(19) The semiconductor device according to (1), further comprising a plurality of lenses provided on a second face of the first substrate, as part of the first substrate.

(20) The semiconductor device according to (3), wherein the first substrate includes a plurality of chip regions and a dicing region, and the second insulating film is provided in at least the dicing region.

(21) A manufacturing method of a semiconductor device, the manufacturing method comprising: forming a plurality of protruding portions that protrude with respect to a first face of the first substrate;

forming a plurality of types of insulating films at least between the protruding portions on the first face of the first substrate;

disposing a second substrate so as to face the first face of the first substrate; and forming a filling material between the first substrate and the second substrate, so as to come into contact with the plurality of types of insulating films.

(22) The manufacturing method of a semiconductor device according to (21), wherein wettability of the plurality of types of insulating films with respect to the filling material differs from each other.

(23) The manufacturing method of a semiconductor device according to (21), wherein the plurality of types of insulating films include a first insulating film, and a second insulating film of a different type from the first insulating film.

(24) The manufacturing method of a semiconductor device according to (21), wherein the protruding portions include a light-emitting element that emits light from the first face of the first substrate to a second face.

(25) The manufacturing method of a semiconductor device according to (21), wherein the protruding portions include a connecting portion that electrically connects the first substrate side and the second substrate side.

### REFERENCE SIGNS LIST

1 Light-emitting device
2 Image-capturing device
3 Control device
11 Light-emitting unit
12 Drive circuit
13 Power source circuit
14 Light-emitting-side optical system
21 Image sensor
22 Image processing unit
23 Image-capturing-side optical system
31 Ranging unit
41 LD chip
42 LDD board
43 Mounting board
44 Thermal dissipation board
45 Correcting lens holding unit
46 Correcting lens
47 Wiring
48 Bump
49 Underfill material
51 Substrate
52 Laminated film
53 Light-emitting element
54 Electrode
55 First insulating film
56 Second insulating film
57 Lens
61 Substrate
62 Connecting pad

What is claimed is:

1. A semiconductor device, comprising:
a first substrate;
a plurality of protruding portions that protrude with respect to a first face of the first substrate;
a plurality of types of insulating films that are provided at least between the protruding portions on the first face of the first substrate;
a second substrate that is provided facing the first face of the first substrate; and
a filling material that is provided between the first substrate and the second substrate, so as to come into contact with the plurality of types of insulating films.

2. The semiconductor device according to claim 1, wherein wettability of the plurality of types of insulating films with respect to the filling material differs from each other.

3. The semiconductor device according to claim 1, wherein the plurality of types of insulating films include a first insulating film, and a second insulating film of a different type from the first insulating film.

4. The semiconductor device according to claim 3, wherein the second insulating film is provided on the first face of the first substrate, via the first insulating film.

5. The semiconductor device according to claim 3, wherein the wettability of the second insulating film with respect to the filling material is higher than the wettability of the first insulating film with respect to the filling material.

6. The semiconductor device according to claim 3, wherein
the first face of the first substrate includes a first region, and a second region in which a density of the protruding portions is lower than in the first region, and
a proportion of an area covered by the second insulating film as to an area of the first face in the second region is higher than a proportion of the area covered by the second insulating film as to the area of the first face in the first region.

7. The semiconductor device according to claim 3, wherein
the first insulating film includes Si (silicon) and N (nitrogen), and
the second insulating film includes Si (silicon) and O (oxygen).

8. The semiconductor device according to claim 1, wherein the protruding portions include a light-emitting element that emits light from the first face of the first substrate to a second face.

9. The semiconductor device according to claim 1, wherein the protruding portions include a connecting portion that electrically connects the first substrate side and the second substrate side.

10. The semiconductor device according to claim 9, wherein the connecting portion includes a bump or solder.

11. The semiconductor device according to claim 1, wherein the plurality of protruding portions are disposed non-uniformly on the first face of the first substrate.

12. The semiconductor device according to claim 1, wherein the filling material is resin.

13. The semiconductor device according to claim 1, wherein the filling material is provided between the first substrate and the second substrate, so as to come into contact with the plurality of types of insulating films and the second substrate.

14. The semiconductor device according to claim 1, wherein the first substrate is a semiconductor substrate that includes gallium (Ga) and arsenic (As).

15. The semiconductor device according to claim 3, wherein the second insulating film is provided on the first face of the first substrate and surfaces of the protruding portions, via the first insulating film.

16. The semiconductor device according to claim 3, wherein the second insulating film is divided into a plurality of portions that come into contact with the filling material.

17. The semiconductor device according to claim 1, wherein the plurality of protruding portions are disposed on the first face of the first substrate so as not to form a regular grid.

18. The semiconductor device according to claim 1, further comprising a plurality of lenses provided on a second face of the first substrate, as part of the first substrate.

19. The semiconductor device according to claim 3, wherein
the first substrate includes a plurality of chip regions and a dicing region, and
the second insulating film is provided in at least the dicing region.

20. A manufacturing method of a semiconductor device, the manufacturing method comprising:
forming a plurality of protruding portions that protrude with respect to a first face of the first substrate;
forming a plurality of types of insulating films at least between the protruding portions on the first face of the first substrate;
disposing a second substrate so as to face the first face of the first substrate; and
forming a filling material between the first substrate and the second substrate, so as to come into contact with the plurality of types of insulating films.
